(19) United States
(12) Patent Application Publication
(10) Pub. No.: US 2011/0163791 A1
(43) Pub. Date: Jul. 7, 2011

(54) OUTPUT CIRCUIT AND SEMICONDUCTOR DEVICE INCLUDING PRE-EMPHASIS FUNCTION

(75) Inventor: Tsuyoshi KANDA, Kanagawa (JP)

(73) Assignee: Renesas Electronics Corporation, Kawasaki (JP)

(21) Appl. No.: 12/984,467

(22) Filed: Jan. 4, 2011

(30) Foreign Application Priority Data
Jan. 5, 2010 (JP) 2010-000555

(51) Int. Cl. H03L 5/00

(52) U.S. Cl. 327/315

(57) ABSTRACT

Disclosed is an output circuit that receives an input signal and that outputs a pre-emphasized output signal when an input signal transitions. The output circuit comprises a transistor applying de-emphasis to the output signal and a de-emphasis level control circuit comprising another transistor controlling a de-emphasis level. The transistor applying de-emphasis and the transistor controlling a de-emphasis level are connected in common to a current source and transistor controlling a de-emphasis level is made conductive at a time of de-emphasis to limit a current flowing through the transistor applying de-emphasis to the output signal.

### TECHNICAL FIELD

### Reference to Related Application

This application is based upon and claims the benefit of the priority of Japanese patent application No. 2010-000555, filed on Jan. 5, 2010, the disclosure of which is incorporated herein in its entirety by reference thereto. The present invention relates to an output circuit, and particularly to an output circuit including a pre-emphasis function and a semiconductor device comprising such an output circuit.

### BACKGROUND

It is common for a differential output circuit in an integrated circuit that transmits a signal to an external integrated circuit via differential transmission lines to transmit a pre-emphasized output signal, taking a transmission line loss into consideration. An output circuit having a pre-emphasis function pre-emphasizes its output signal when a current bit data to be outputted is different from a bit data outputted immediately before, and does not pre-emphasize it when there is no change.

In a differential output circuit having a pre-emphasis function, there is a case where a transition bit which has transitioned from a value of bit data immediately before and is pre-emphasized, and a de-emphasis bit which is the same as the value of the bit data immediately before and is not pre-emphasized, do not have the same common mode voltage (VCM), which is a midpoint voltage of differential output signals. When the common mode voltage (VCM) varies greatly between a transition bit and a de-emphasis bit, there may be a possibility of deviating from a standard interface protocol, such as PCI Express, Serial ATA, CEI or the like.

FIG. 10 shows examples of AC common mode voltage (Vcmac: AC coupled common mode voltage) specifications of several standard interface protocols. Output circuits compatible with these standard interface protocols are required to operate at a low power supply voltage in order to reduce power consumption. The variation in the common mode voltage (VCM) due to a mismatch in the common mode voltage (VCM) between a transition bit and a de-emphasis bit tends to be great when realizing a large differential output amplitude (between 800 mV and 1200 mV) with a low power supply voltage as in case of PCI Express. Therefore, the need to reduce and suppress variation in the common mode voltage (VCM) has increased. Below, related technologies of an output circuit equipped with a pre-emphasis function (without a function of suppressing a variation in VCM) and an output circuit equipped with a function of suppressing a variation in VCM will be described in order.

FIG. 5 is a diagram showing a configuration of an output circuit equipped with a pre-emphasis function (refer to Patent Document 1). In FIG. 5, the output circuit comprises a driver main buffer 10 and a pre-emphasis buffer 20. The driver main buffer 10 comprises an NMOS transistor N11 (current source transistor) having a source connected to a low-potential power supply VSS (VSS is for instance a ground potential) and having a gate supplied with a bias voltage BIAS; NMOS transistors N1 and N2 (a differential pair) having sources connected in common to a drain of the current source transistor N11, having gates respectively connected to first and second input terminals INT and INB which constitute differential input terminals, and having drains respectively connected to a first output terminal OUTB (also referred to as “reverse-phase output terminal” or “inverted output terminal”) of differential output terminals and a second output terminal OUTT (also referred to as “the positive phase output terminal” or “non-inverted output terminal”) of the differential output terminals; and resistor elements R1 and R2 respectively connected between OUTB and OUTT (i.e., the drains of the NMOS transistors N1 and N2) and a high-potential power supply VDD. The sizes and characteristics of the NMOS transistors N1 and N2 constituting a differential pair are identical with each other.

The pre-emphasis buffer 20 comprises an NMOS transistor N12 (current source transistor) having a source connected to the low-potential power supply VSS and having a gate supplied with a bias voltage BIAS, and NMOS transistors N3 and N4 having sources connected in common to a drain of the current source transistor N12, having gates respectively connected to first and second control signal terminals EMT and EMB which differentially receive control signals (emphasis signals), and having drains respectively connected to the first and second output terminals OUTB and OUTT. The sizes and characteristics of the NMOS transistors N3 and N4 constituting a differential pair are identical with each other. In the terminals and signal names such as OUTT, OUTB, EMT, and EMB, the last “T” denotes a positive phase (True) and “B” denotes a reversed phase (Bar).

FIG. 6 is a timing chart for explaining the operation of the circuit shown in FIG. 5. The timing chart shown in FIG. 6 is diagram newly created by the inventor of the present application in order to describe the operation of the circuit shown in FIG. 5. FIG. 6 shows voltage waveforms of terminals INT and INB, terminals EMT and EMB, terminal OUTB, a common mode voltage (VCM), a terminal OUTT, a drain node VS2 of the NMOS transistor N12, and a drain node VS1 of the NMOS transistor N11, all shown in FIG. 5, and ON and OFF states of the NMOS transistors N1, N2, N3, and N4. In FIG. 6, (1) to (11) above the INT row denote timing periods. The operation of the circuit in FIG. 5 will be described with reference to the timing chart. Note that a name of a terminal will be also used as a name of the signal at the terminal.

### [Period (1)]

When (INT, INB) transition from (Low, High), the values immediately before, to (High, Low) (a case of the transition bit), (EMT, EMB)=(High, Low). The NMOS transistors N1 and N3 turn ON (conductive), the NMOS transistors N2 and N4 turn OFF (nonconductive), and OUTT and OUTB become pre-emphasized High voltage VOHP and Low voltage VOLP respectively. The High voltage VOHP at OUTT is for instance the power supply voltage VDD. Further, when the drain currents of the NMOS transistors N1 and N3 are I1 and I3, the Low voltage VOLP at OUTB can be given as follows.

VOLP=VDD−R1×(I1+I3)

Here, since the NMOS transistors N2 and N4 are OFF, the drain currents I1 and I3 of the NMOS transistors N1 and N3 are equal to the current values of the current sources N11 and N12 respectively. As described, since the Low voltage VOLP at OUTB goes low and the NMOS transistors N1 and N3 are ON, the voltages at the drain node VS1 (the commonly coupled source nodes of the NMOS transistors N1 and N2) of the current source transistor N11 and at the drain node VS2 (the coupled source nodes of the NMOS transistors N3 and N4) of the current source transistor N12 decrease. In FIG. 6, Va denotes the drain voltage VS2 of the current source transistor N12 at this time.

### [Period (2)]

When (INT, INB) do not change from (High, Low) (a case of the de-emphasis bit), (EMT, EMB) are set to (Low, High). During Period (2), the NMOS transistors N1 and N2 continues to be ON and OFF, respectively. However, since EMT=Low and EMB=High, the NMOS transistor N3 turns OFF and the NMOS transistor N4 turns ON. The waveforms of (OUTT, OUTB) are de-emphasized. Since the NMOS transistor N3 is OFF, a de-emphasized Low voltage VOLD at OUTB is given as follows.

VOLD=VDD−R1×I1

In other words, the de-emphasized Low voltage VOLD at OUTB in Period (2) is higher than the pre-emphasized Low voltage VOLP (=VDD−R1×(I1+I3)) at OUTB in Period (1), in which the NMOS transistors N1 and N3 are both ON, by an amount of R1×I3.

Further, since the NMOS transistor N4 is ON, a de-emphasized High voltage VOHD at OUTT is given as follows.

VOHP=VDD−R2×I4

(where I4 is a drain current of the NMOS transistor N4.)

In other words, the de-emphasized High voltage VOHD at OUTT in Period (2) is lower by a voltage of R2×I4 than the pre-emphasized High voltage VOHP (=VDD) in Period (1), in which the NMOS transistors N2 and N4 are both OFF.

As described, in the pre-emphasis buffer 20, whereas the NMOS transistor N3 turns ON and the NMOS transistor N4 turns OFF in Period (1), the NMOS transistor N3 turns OFF and the NMOS transistor N4 turns ON in Period (2). Since the NMOS transistor N4 having a drain connected to OUTT at the High voltage VOHD, turns ON, during Period (2), the voltage at the drain node VS2 of the current source transistor N12 increases from Va in Period (1) to Vb.

FIG. 7 shows the characteristic of a drain-to-source voltage Vds (x-axis) and a drain current Id (y-axis) of the current source transistor N12 in the pre-emphasis buffer 20 of the circuit shown in FIG. 5. As shown in the Vds-Id characteristic shown in FIG. 7, because of the fact that the drain node VS2 voltage (drain-to-source voltage) of the current source transistor N12 operating in a saturation region increases from Va to Vb, a drain current value Id of the NMOS transistor N12 increase from Ia to Ib by an amount of dI.

As described, during Period (2), because of the increase in the drain node VS2 voltage of the current source transistor N12, the drain current value of the current source transistor N12 increases, the value of the current flowing through a path from OUTT to the transistor N4 to the transistor N12 increases, the voltage drop of the resistor element R2 increases, and the de-emphasized High voltage VOHD at OUTT decreases. As a result, the common mode voltage (VCM) in Period (2) is lower than the common mode voltage (VCM) in Period (1).

### [Period (3)]

When (INT, INB) transition to (Low, High) (a case of the transition bit), (EMT, EMB)=(Low, High). Since INT transitions from High to Low, the NMOS transistor N1 turns OFF and the NMOS transistor N2 turns ON. Further, since EMT=Low and EMB=High, the NMOS transistor N3 turns OFF and the NMOS transistor N4 turns ON. OUTT and OUTB become the pre-emphasized Low voltage VOLP and High voltage VOHP, respectively. Assuming that drain currents of the NMOS transistors N2 and N4 are 12 and 14, VOLP at OUTT is VDD−R2×(I2+I4), and VOHP at OUTB becomes VDD. Since the NMOS transistors N2 and N4 having drains connected to OUTT (at the voltage VOLP) are in a ON state, the voltages at the drain nodes VS1 and VS2 of the current source transistors N11 and N12 decrease. During Period (3), the voltage at the drain node VS2 of the current source transistor N12 drops from Vb in Period (2) to Va. The common mode voltage (VCM) in Period (3) is essentially identical to the common mode voltage (VCM) in Period (1).

### [Period (4)]

During Period (4), (INT, INB) are kept at (Low, High) as in Period (3) (a case of the de-emphasis bit); therefore (EMT, EMB)=(High, Low). During Period (4), the NMOS transistor N1 continues to be in an OFF state and the NMOS transistor N2 continues to be in an ON state. The NMOS transistor N3 turns ON, since EMT=High, and the NMOS transistor N4 turns OFF, since EMB=Low. OUTT and OUTB become the de-emphasized Low voltage VOLD and High voltage VOHD, respectively.

In the pre-emphasis buffer 20, whereas the NMOS transistor N4 turns ON and the NMOS transistor N3 turns OFF during Period (3), the NMOS transistor N4 turns OFF and the NMOS transistor N3 turns ON during Period (4). Since the NMOS transistor N3 having its drain connected to OUTB at the High voltage VOHD, turns ON, during Period (4), the voltage at the drain node VS2 of the current source transistor N12 increases from Va in Period (3) to Vb. For the same reason as in Period (2), a drain current of the current source transistor N12 increases by the amount of dI (refer to FIG. 7). Because of the increase in the drain current value of the current source transistor N12, the value of the current flowing through a path from OUTB, through the transistor N3 to the transistor N12 increases, the voltage drop of the resistor element R1 increases, and the common mode voltage (VCM) of the de-emphasis bit drops from the common mode voltage (VCM) during Period (3). Further, during Period (4), (INT, INB) continue to be (Low, High) for two cycles.

Periods (1) to (4) are repeated in Periods (5) to (11). Further, during Period (11), (INT, INB) continue to be (High, Low) for three consecutive cycles.

A logic circuit that generates signals EMT and EMB controlling the pre-emphasis function, from the input signals INT and INB is well known and implemented in a variety of ways. For instance, with regard to a current bit and a bit immediately before (held in a flip-flop) supplied to INT, the signal EMT is given as follows.

When (a current bit, a bit immediately before)=(High, Low), EMT=High.

When (a current bit, a bit immediately before)=(High, High), EMT=Low.

When (a current bit, a bit immediately before)=(Low, High), EMT=Low.

When (a current bit, a bit immediately before)=(Low, Low), EMT=High.

(It is to be noted that EMT assumes an inverted value of the bit immediately before.)

EMB is the complementary signal of EMT.

Since the output circuit shown in FIG. 5 does not comprise a function of controlling a variation in VCM, as described above, a mismatch in the common mode voltage (VCM) between a transition bit and a de-emphasis bit may occur and the variation in VCM may increase (degrade). In other words, unless the specifications should be changed such as increasing a power supply voltage or reducing an output amplitude, there is a possibility of deviating from standard interface protocols such as PCI Express, Serial ATA, and CEI. As shown in FIG. 10, in SATA (Serial Advanced Technology Attachment), the AC common mode voltage variation (Vcmac) is specified at 50 mVpp.

An output circuit compatible with a standard interface protocol is required to operate at a low power supply voltage in order to reduce power consumption. In the circuit shown in FIG. 5, when a large differential output amplitude (between 800 mV and 1200 mV) with a low power supply voltage such as in a case with PCI Express is to be achieved, the variation in the common mode voltage (VCM) between a transition bit and a de-emphasis bit increases. When the variation in VCM increases, a delay when a receiver circuit (differential receiver circuit) receives differential signals from the differential output terminals OUTT and OUTB varies, this delay variation results in a jitter, the time interval in which the receiver circuit is able to receive the signal is reduced, and a jitter tolerance deteriorates.

FIG. 8 is a diagram showing a general circuit configuration that stabilizes VCM using a feedback circuit. With reference to FIG. 8, the circuit comprises a driver main buffer 10′, a pre-emphasis buffer 20′, and a VCM feedback circuit 21. The driver main buffer 10′ further comprises resistor elements R1 and R2 (load resistor elements) having first ends connected to drains of the NMOS transistors N1 and N2 and the second ends connected in common and a PMOS transistor P1 between the commonly connected second ends of the resistor elements R1 and R2 and the high-potential power supply VDD in the configuration shown in FIG. 5. The VCM feedback circuit 21 comprises an operational amplifier (OPAMP) that has a non-inverting input that receives a midpoint voltage COM (voltage of a connection node of resistor elements R3 and R4 connected in series between OUTT and OUTB) of OUTT and OUTB in the pre-emphasis buffer 20′, has an inverting input that receives a common mode reference voltage (VCMREF), and has an output connected to a gate of the PMOS transistor P1. The operational amplifier (OPAMP) controls the gate voltage of the PMOS transistor P1 so that the midpoint voltage (common mode voltage) (COM) matches VCMREF, and by adjusting the drain voltage VD1 (voltage of the connection node of the load resistor elements R1 and R2) of the PMOS transistor P1, the common mode voltage (COM) is fed-back controlled. In this method for stabilizing VCM, the following speed depends on the following speed of the feedback circuit including the operational amplifier (OPAMP) and the PMOS transistor P1. Therefore, the circuit in FIG. 8 is effective for VCM variation not greater than, for instance, several tens MHz. The circuit in FIG. 8 cannot follow and cope with VCM high-speed variation exceeding 1 GHz such as the VCM variation between a transition bit and a de-emphasis bit in standard interface protocols such as PCI Express, Serial ATA, and CEI.

In Patent Document 1, as shown in FIG. 4 of thereof, a variation in the common mode voltage VCM at a time of de-emphasis is compensated by providing two PMOS transistors having drains respectively connected to the drains of the NMOS transistors N3 and N4 of the pre-emphasis buffer of the circuit shown in FIG. 5, and providing a third PMOS transistor between commonly coupled sources of these two PMOS transistors and the power supply VDD. In this configuration, the transistors are cascade-connected in four stages, and the circuit is not suitable for operation at a low power supply voltage. Further, since the PMOS transistors are connected to the resistor elements R1 and R2 in parallel, a DC impedance decreases.

FIG. 9 shows the configuration of an output circuit (current mode logic driver) disclosed in Patent Document 2. FIG. 9 has been created based on FIG. 5 of Patent Document 2. In FIG. 9, the driver main buffer 10 and the pre-emphasis buffer 20 are configured as shown in FIG. 5. As shown in FIG. 9, the circuit comprises a level shifting mechanism comprising a current source Ipu of a VCM pull up mechanism between a high-potential power supply VDD and OUTT, a current source Ipd of a VCM pull down mechanism between OUTT and a low-potential power supply VSS, a current source Ipu of the VCM pull up mechanism between the high-potential power supply VDD and OUTB, and an Ipd of the VCM pull down mechanism between OUTB and the low-potential power supply VSS. The resistor element R3 connected between the differential output terminals OUTT and OUTB of the output circuit is a load resistor.

In the investigation below, it is assumed that the pre-emphasis buffer 20 is not operating (i.e., the NMOS transistors N3 and N4 are both in an OFF state) for the sake of simplicity. Meanwhile, it is assumed that the NMOS transistor N1 is ON, and the NMOS transistor N2 is OFF. The circuit has two current paths: I1 and I2, and the current value is determined by the ratio among the resistor elements R1, R2, and R3. The output terminal OUTT outputs a High level (VOH), which is given:

VOH=VDD−I2×R2.

The output terminal OUTB outputs a Low level (VOL), which is given:

VOL=VDD−I1×R1.

The common mode voltage (VCM) is given as follows:

$$\begin{matrix}VCM = ( VOH + VOL ) / 2 \\ = VDD - ( I 1 \times R 1 + I 2 \times R 2 ) / 2.\end{matrix}$$

When the common mode voltage (VCM) is to be raised, the two constant current sources Ipus of the VCM pull up mechanism connected between the differential output terminals (OUTT, OUTB) and the power supply VDD are both turned ON, and the two constant current sources Ipds of the VCM pull down mechanism connected between the differential output terminals (OUTT, OUTB) and GND (VSS) are both turned OFF.

At this time, the output High level is:

VOH=VDD−(I2−Ipu)×R2; and

the output Low level is:

VOL=VDD−(I1−Ipu)×R1.

The common mode voltage (VCM) is:

$$\begin{matrix}VCM = ( VOH + VOL ) / 2 \\ = VDD - ( I 1 \times R 1 + I 2 \times R 2 ) / 2 + \\ Ipu \times ( R 1 + R 2 ) / 2.\end{matrix}$$

The potential of VCM is raised by an amount of Ipu×(R1+R2)/2.

When the common mode voltage (VCM) is to be lowered, the two constant current sources Ipus of the VCM pull up mechanism connected between the differential output terminals (OUTT, OUTB) and the power supply VDD are turned OFF, and the two constant current sources Ipds of the VCM pull down mechanism connected between the differential output terminals (OUTT, OUTB) and GND (VSS) are turned ON. At this time, the output High level is:

VOH=VDD−(I2−Ipd)×R2; and

the output Low level is:

VOL=VDD−(I1−Ipd)×R1.

The common mode voltage (VCM) is:

$$\begin{matrix}VCM = ( VOH + VOL ) / 2 \\ = VDD - ( I 1 \times R 1 + I 1 \times R 2 ) / 2 - \\ Ipd \times ( R 1 + R 2 ) / 2.\end{matrix}$$

The potential of VCM is lowered by an amount equal of Ipd×(R1+R2)/2.

As described, VCM can be adjusted by controlling the current values of the constant current source Ipu of the VCM pull up mechanism connected between the output terminals (OUTT, OUTB) and the power supply (VDD), and of the constant current source Ipd of the VCM pull down mechanism connected between the output terminals (OUTT, OUTB) and GND (VSS).

### [Patent Document 1]

US2008/0001630A1

### [Patent Document 2]

Japanese Patent Kokai Publication No. JP2004-350272A

### SUMMARY

An analysis on the related technologies by the present invention is given below.

The output circuit shown in FIG. 9 adjusts the common mode voltages (VCM) of both an output waveform of a pre-emphasized transition bit and an output waveform of a de-emphasis bit. Further, in the output circuit shown in FIG. 9, the PMOS transistors constituting the two constant current sources Ipus of the VCM pull up mechanism and the constant current source transistor of the VCM pull down mechanism are respectively connected to the differential outputs OUTT and OUTB. When the power supply voltage VDD is lowered in order to reduce power consumption, there is a limit in the configuration shown in FIG. 9 in which the common mode voltage (VCM) is simply pulled down, and a shift in the common mode voltage (VCM) between a transition bit and a de-emphasis bit cannot be resolved. Therefore, there is a need for a function of being able to adjust the common mode voltage (VCM) only for a de-emphasis bit (the result of the analysis by the present inventor).

A constant current source transistors should have an infinite output impedance ideally. However, the impedance decreases in reality, and it is even more difficult to maintain a high impedance when a power supply voltage is lowered. In the circuit shown in FIG. 9, if an output impedances of the constant current sources connected to the output terminals OUTT and OUTB decrease, an impedance of the output circuit will drop, and hence there is a possibility of deviating from standard interface protocols (PCI Express, Serial ATA, and CEI).

The constant current source is connected to each of the output terminals OUTT and OUTB in the circuit shown in FIG. 9. As a result, the circuit cannot operate at high-speed due to a large capacitance of each of diffusion layers attached respectively to the output terminals OUTT and OUTB.

A technique invented so as to solve one or more problems described above will be presented below, though not limited thereto.

In accordance with one aspect of the present invention, there is provided a output circuit (semiconductor device) outputting a pre-emphasized output signal when an input signal transitions and comprising a circuit that limits a current flowing through a transistor allying de-emphasis to the output signal at a time of de-emphasis when the input signal does not change from a pre-emphasis state, and that controls to reduce an amount of a change of a voltage in the output signal from a time of pre-emphasis to a time of de-emphasis.

In accordance with one of exemplary embodiments of the present invention, there is provided an output circuit that receives an input signal and that outputs differentially a pre-emphasized output signal when the input signal transitions, wherein the output circuit comprising:

a transistor (for example, N4/N3) applying de-emphasis to the output signal, the transistor being made conductive responsive to a control signal applied to a control terminal of the transistor (N4) at a time of de-emphasis when the input signal does not change from a pre-emphasis state; and

a de-emphasis level control circuit (30) that performs control so as to reduce an amount of a change (variation) in a common mode voltage of the output signal, which is differentially output, from a pre-emphasis state to a de-emphasis state and that includes

another transistor (for example, N6/N5) controlling a de-emphasis level of the output signal,

the another transistor (N6/N5) and the transistor (N4/N3) applying de-emphasis to the output signal having first terminals connected in common to a current source (for example, N13/N12) which is connected to a first power supply (VSS) and having second terminals connected to a second power supply (VDD) and an output terminal (for example, OUTT/OUTB), respectively. The another transistor (N6/N5) is made conductive at a time of de-emphasis to limit a current flowing through the transistor (N4/N3) applying de-emphasis to the output signal at a time of de-emphasis.

According to the present invention, a variation of a common mode voltage of differential output signals at a time of de-emphasis from a common mode voltage at a time of pre-emphasis can be reduced while the circuit configuration is simplified.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of an example of the present invention.

FIG. 2 is a timing chart for explaining the operation of an example of the present invention.

FIGS. 3A and 3B are diagrams showing the configuration of an example of the present invention.

FIG. 4 is a diagram showing simulation results in an example of the present invention.

FIG. 5 is a diagram showing the configuration of a first related technology.

FIG. 6 is a timing chart for explaining the operation of the first related technology.

FIG. 7 is a diagram showing the characteristics of the drain-source voltage (Vds) and the drain current (Id) of a MOS transistor.

FIG. 8 is a diagram showing the configuration of a second related technology.

FIG. 9 is a diagram showing the configuration of a third related technology.

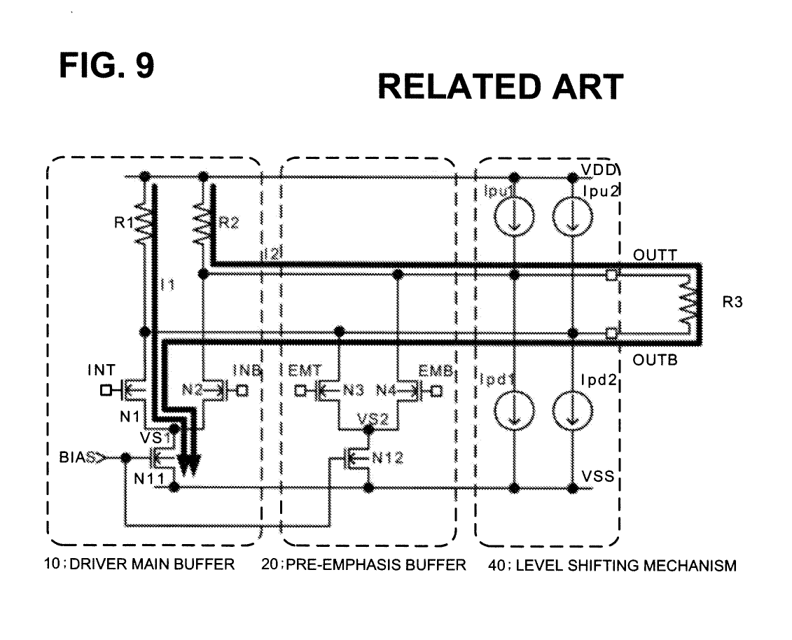

FIG. 10 is a diagram showing examples of AC common mode voltage specifications of several standard interface protocols.

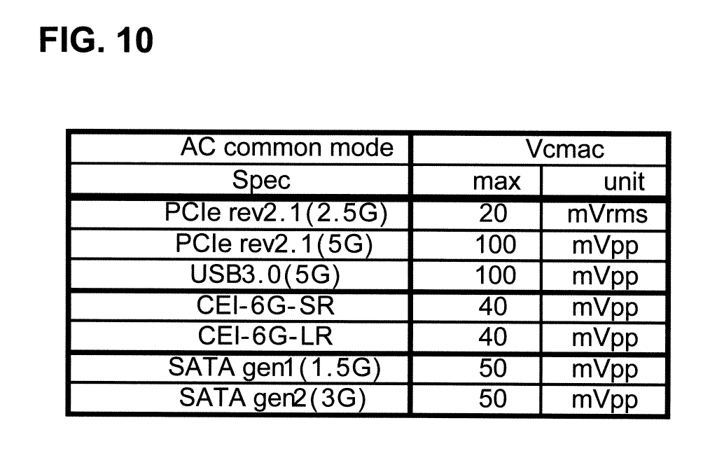

### PREFERRED MODES

The present invention will be described below. In one of preferred modes of the present invention, there is provided an output circuit comprises:

first and second transistors (N1, N2) constituting a first transistor pair;

third and fifth transistors (N3, N5) constituting a second transistor pair;

fourth and sixth transistors (N4, N6) constituting a third transistor pair; and

first to third current sources (N11, N12, N13) respectively connected between the first to the third transistor pairs and a first power supply (VSS) and respectively, each of the first to third current sources supplying a constant current to each of the first to the third transistor pairs.

In the present invention, the first and the second transistors (N1, N2) have first terminals (source terminals) connected in common to the first current source (transistor N11), have control terminals (gate terminals) respectively connected to first and second input terminals (INT, INB) that receives complementary input signals, and have second terminals (drain terminals) respectively connected to first and second output terminals (OUTB, OUTT).

In the present invention, the first current source (transistor N11) has a first terminal (source terminal) connected to the first power supply (VSS), has a second terminal (drain terminal) connected to the commonly coupled first terminals (source terminals) of the first and the second transistors (N1, N2), and has a control terminal (gate terminal) supplied with a bias voltage (BIAS).

In the present invention, first and second resistor elements (R1, R2) are connected respectively between the first and the second output terminals (OUTB, OUTT) and a second power supply (VDD).

In the present invention, the third and the fifth transistors (N3, N5) have first terminals (source terminals) connected in common to the second current source (transistor N12), have control terminals connected to a first control signal terminal (EMT) supplied with a control signal that controls pre-emphasis processing and to the second input terminal (INB), respectively, and have second terminals (drain terminals) connected to the first output terminal (OUTB) and to an end of a third resistor element (R3), respectively. The other end of the third resistor element (R3) is connected to the second power supply (VDD).

In the present invention, the second current source (transistor N12) has a first terminal (source terminal) connected to the first power supply (VSS), has a second terminal (drain terminal) connected to the commonly coupled first terminals (source terminals) of the third and the fifth transistors (N3, N5), and has a control terminal (gate terminal) supplied with the bias voltage (BIAS).

In present invention, the fourth and the sixth transistors (N4, N6) have first terminals (source terminals) connected in common to the third current source (transistor N13), have control terminals connected to a second control signal terminal (EMB) supplied with a signal complementary to the control signal that controls pre-emphasis processing and to the first input terminal (INT), respectively, and have second terminals (drain terminals) connected to the second output terminal (OUTT) and to an end of the third resistor element (R3), respectively.

In the present invention, the third current source (transistor N13) has a first terminal (source terminal) connected to the first power supply (VSS), has a second terminal (drain terminal) connected to the commonly coupled first terminals (source terminals) of the fourth and the sixth transistors (N4, N6), and has a control terminal supplied with the bias voltage (BIAS). The bias voltages of the first to the third current sources (transistors N11 to N13) are common. A mode of operation in the present invention will be described.

(1) When INT Transitions from Low Immediately Before to High (at a Time of Pre-Emphasis)

The first and the second input terminals (INT, INB) transition from (Low, High) immediately before to (High, Low), and the first and the second control signal terminals (EMT, EMB)=(High, Low).

INT is at High, and hence the first and the sixth transistors (N1, N6) both turn ON (conductive).

EMT is at High, and hence the third transistor (N3) turns ON (conductive).

INB is at Low, and hence the second transistor (N2) turns OFF (nonconductive).

EMB is at Low, and hence the fourth transistor (N4) turns OFF (nonconductive).

The first output terminal (OUTB) goes to a pre-emphasized Low voltage (VOLP) and the second output terminal (OUTT) goes to a pre-emphasized High voltage (VOHP), where the High voltage (VOHP) at the second output terminal (OUTT) is equal to the second supply voltage (VDD) and the Low voltage (VOLP) at the first output terminal (OUTB) is obtained by subtracting an amount of a voltage drop across the first resistor (R1) from the second supply voltage (VDD) caused by a sum of the currents respectively flowing through the first and the third transistors (N1, N3) that are in a conductive state.

### (2) When INT Maintains High (at a Time of De-Emphasis).

When the first and the second input terminals (INT, INB) maintain (High, Low), the first and the second control signal terminals (EMT, EMB) are set to (Low, High).

INT is at High, and hence the first and the sixth transistors (N1, N6) remain ON (conductive).

INB is at Low, and hence the fifth transistor (N5) remains OFF.

EMT is at Low, and hence the third transistor (N3) turns OFF (nonconductive).

EMB is at High, and hence the fourth transistor (N4) turns ON (conductive).

The sixth transistor (N6) that is connected in common with the fourth transistor (N4) to the third current source (N13) is in an ON state. A sum of the currents flowing through the sixth transistor (N6) and the fourth transistor (N4) is equal to the current value of the third current source (N13). Therefore, a current flowing through the fourth transistor (N4) can be obtained by subtracting a current flowing through the sixth transistor (N6) from a current value of the third current source (N13). The second output terminal (OUTT) goes to a voltage obtained by subtracting from the second supply voltage (VDD), an amount of a voltage drop of the second resistor (R2) caused by the current flowing through the fourth transistor (N4), and this is a High voltage (VOHD) at a time of de-emphasis.

According to the present invention, a drop of the High voltage (VOHD) at the second terminal (OUTT) at a time of de-emphasis from the High voltage (VOHP) at a time of pre-emphasis is mitigated by limiting, at a time of de-emphasis, a current (circuit current for de-emphasis) flowing through the fourth transistor (N4) connected to the second output terminal (OUTT) to a current value equal to an amount obtained by subtracting a predetermined amount from the current value of the third current source (N13).

At a de-emphasis time, the third transistor (N3) turns OFF and only the current flowing through the first transistor (N1) flows through the first resistor (R1). Therefore, a Low voltage (VOLD) at the first output terminal (OUTB) becomes higher than the Low voltage (VOLP) at a time of pre-emphasis. As a result, the common mode voltage VCM (=(VODH+VODL)/2) of the differential output signals at a time of de-emphasis is approximately equal to VCM (=(VOHP+VOLP/2) at a time of pre-emphasis.

(3) When INT Transitions from High Immediately Before to Low (at a Time of Pre-Emphasis)

The first and the second input terminals (INT, INB) transition from (High, Low) to (Low, High), and the first and the second control signal terminals (EMT, EMB) become (Low, High). At this time, the second, the fourth, and the fifth transistors (N2, N4, N5) turn ON (conductive), the first, the third, and the sixth transistors (N1, N3, N6) turn OFF (nonconductive), and the first and the second output terminals (OUTB, OUTT) go to the pre-emphasized High and Low voltages (VOHP, VOLP), respectively. The High voltage at the first output terminal (OUTB) goes to the second supply voltage (VDD) and the Low voltage (VOLP) at the second output terminal (OUTT) goes to a voltage obtained by subtracting an amount of the voltage drop of the second resistor (R2) caused by the sum of the currents flowing through the second and the fourth transistors (N2, N4) from the second supply voltage (VDD).

### (4) When INT Maintains Low (at a Time of De-Emphasis).

When the first and the second input terminals (INT, INB) maintain (Low, High), the first and the second control signal terminals (EMT, EMB) are set to (High, Low).

INB is at High, and hence the second and the fifth transistors (N2, N5) remain ON (conductive).

INT is at Low, and hence the first and the sixth transistors (N1, N6) remains OFF.

EMB is at Low, and hence the fourth transistor (N4) turns OFF (nonconductive).

EMT is at High, and hence the third transistor (N3) turns ON (conductive).

The third transistor (N3) connected in common with the fifth transistor (N5) to the second current source (N12) is in an ON state, and a sum of currents flowing through the fifth transistor (N5) and the third transistor (N3) is equal to the current value of the second current source (N12). Therefore, a current flowing through the third transistor (N3) can be obtained by subtracting a current flowing through the fifth transistor (N5) from a current value of the second current source (N12). The first output terminal (OUTB) goes to a voltage obtained by subtracting from the second supply voltage (VDD) an amount of a voltage drop across the first resistor (R1) caused by the current flowing through the third transistor (N3), and this is the High voltage (VOHD) at a time of de-emphasis.

According to the present invention, the drop of the High voltage (VOHD) at the first terminal (OUTB) at a time of de-emphasis is mitigated by limiting, at a time of de-emphasis, a value of a current flowing through the third transistor (N3) connected to the first output terminal (OUTB) to a current value equal to an amount obtained by subtracting a predetermined amount from the current value of the second current source (N12).

Further, at a time of de-emphasis, the fourth transistor (N4) turns OFF and only the current flowing through the second transistor (N2) flows through the second resistor (R2), and hence the Low voltage (VOLD) at the second output terminal (OUTT) is higher than the Low voltage (VOLP) at a time of pre-emphasis.

As a result, VCM (=(VODH+VODL)/2) at a time of de-emphasis is able to be made close to or approximately equal to VCM (=(VOHP+VOLP)/2) at a time of pre-emphasis. As described, according to the present invention, an amount of a change (variation) of the common mode voltage of the differential output signals at a time of de-emphasis from a time of pre-emphasis can be mitigated by a simple configuration, the power supply voltage can be reduced, and a high-speed operation can be achieved. Examples will be described below.

### Example 1

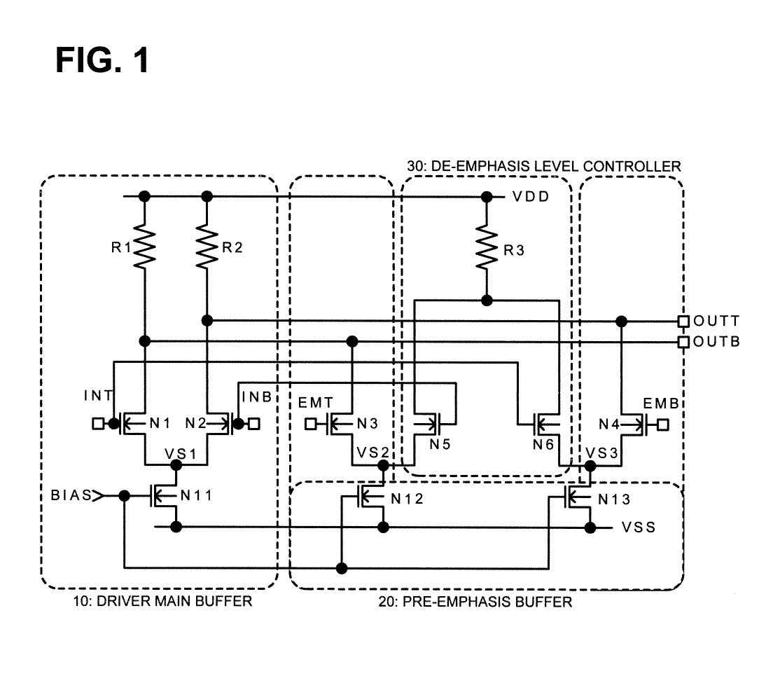

FIG. 1 is a diagram showing the configuration of Example 1 of the present invention. With reference to FIG. 1, a circuit comprising a pre-emphasis function of Example 1 comprises a driver main buffer 10, a pre-emphasis buffer 20, and a de-emphasis level controller 30. The configuration shown in FIG. 1 functions as an output circuit in a semiconductor device. Other parts in the semiconductor device, such as internal circuits, which are unrelated to the subject of the present invention, are omitted for the sake of simplicity, in FIG. 1.

The driver main buffer 10 comprises:

an NMOS transistor N11 that has a source connected to a power supply VSS and has a gate supplied with a bias voltage BIAS; and

NMOS transistors N1 and N2 that constitutes a differential pair and that have gates connected to first and second input terminals INT and INB, respectively, have sources connected in common to a drain of the NMOS transistor N11, and have drains connected to a high-potential power supply VDD via first and second resistor elements R1 and R2, respectively. A connection node of the first resistor element R1 and the drain of the NMOS transistor N1 is connected to a first output terminal OUTB, and a connection node of the second resistor element R2 and the drain of the NMOS transistor N2 is connected to a second output terminal OUTT.

The pre-emphasis buffer 20 comprises:

an NMOS transistor N12 that has a source connected to the low-potential power supply VSS and has a gate supplied with a bias voltage BIAS;

an NMOS transistor N3 that has a source connected to a drain of the NMOS transistor N12, has a gate connected to a first control signal terminal EMT, and has a drain connected to the first output terminal OUTB;

an NMOS transistor N13 that has a source connected to the low-potential power supply VSS and has a gate supplied with a bias voltage BIAS; and

an NMOS transistor N4 that has a source connected to a drain of the NMOS transistor N13, has a gate connected to a second control [signal] terminal EMB, and has a drain connected to the second output terminal OUTT.

The de-emphasis level controller 30 comprises:

an NMOS transistor N5 that has a source connected in common with the source of the NMOS transistor N3 to the drain of the NMOS transistor N12 and has a gate connected to the second input terminal INB;

an NMOS transistor N6 that has a source connected in common with the source of the NMOS transistor N4 to the drain of the NMOS transistor N13, has a gate connected to the first input terminal INT, and has a drain connected to a drain of the NMOS transistor N5; and

a third resistor element R3 that is connected between a connection node of the drains of the NMOS transistors N5 and N6 and the high-potential power supply VDD.

It should be noted that the circuit blocks surrounded by the reference numerals 10, 20, and 30 in FIG. 1 are divided only for the sake of explanation, and the names of circuit blocks and the way the circuits are divided are not limited to the example shown in FIG. 1.

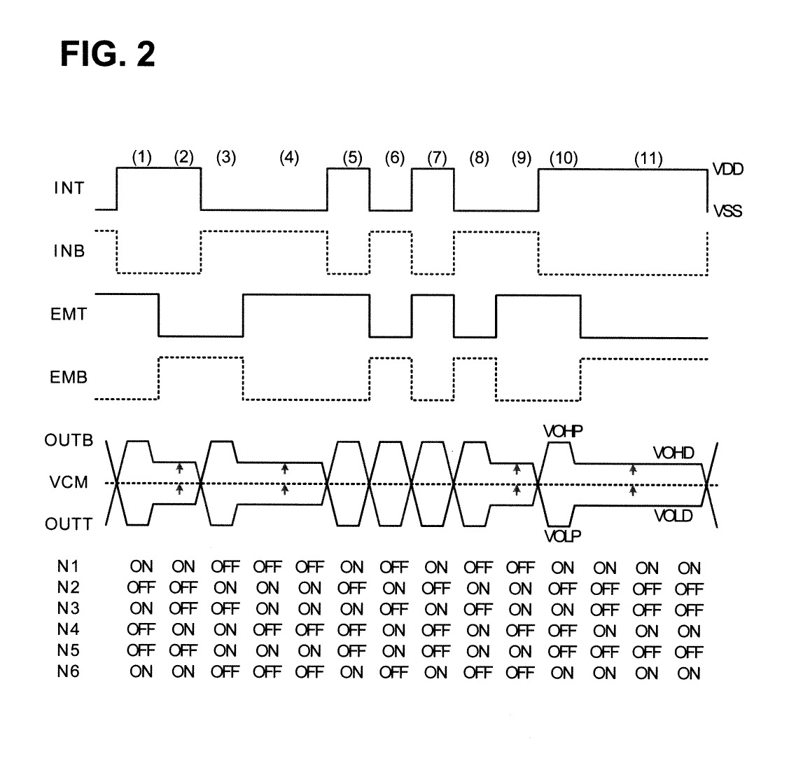

FIG. 2 is a diagram showing timing waveforms of Example 1. FIG. 2 shows the voltage waveforms of the terminals INT, INB, EMT, EMB, OUTB, VCM (the common mode voltage), and the terminal OUTT, and the ON (conductive) and OFF (nonconductive) states of the NMOS transistors N1 to N6. Further, in FIG. 2, (1) to (11) above the INT row denote timing periods.

### [Period (1)]

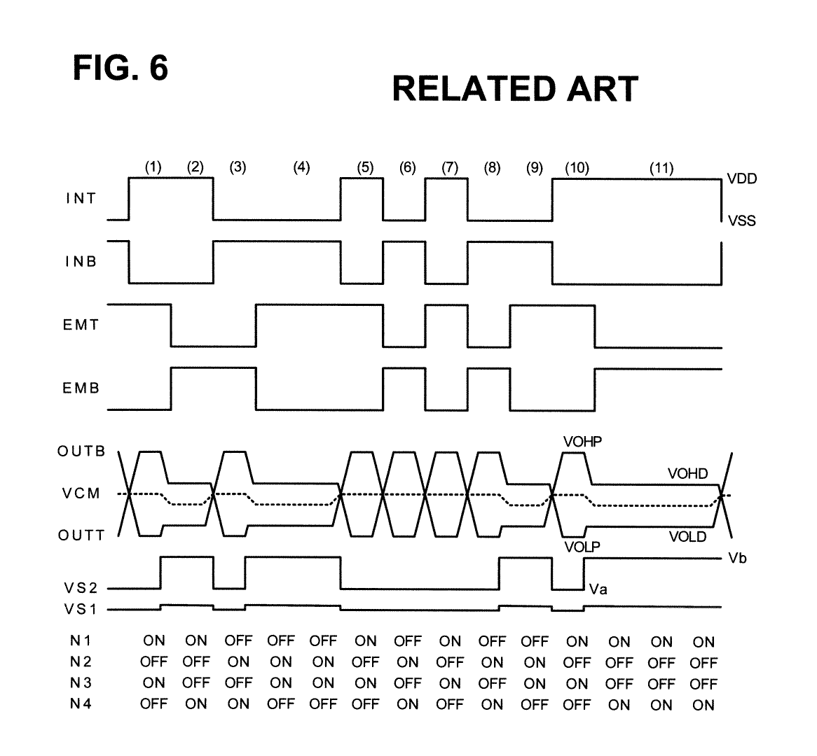

When (INT, INB) transition from (Low, High) to (High, Low), (EMT, EMB)=(High, Low) as in FIG. 6. At this time, the NMOS transistors N1 in the driver main buffer 10 turns ON and so does the NMOS transistor N3 in the pre-emphasis buffer 20. Meanwhile, the NMOS transistors N2 in the driver main buffer 10 turns OFF and so does the NMOS transistor N4 in the pre-emphasis buffer 20. The NMOS transistor N6 in the de-emphasis level controller 30 turns ON, and a current flows from the high-potential power supply VDD to VSS via the third resistor element R3 and the NMOS transistors N6 and N12. Further, at this time, the NMOS transistor N5 in the de-emphasis level controller 30 is OFF. Therefore, no current flows through the NMOS transistor N5 from the high-potential power supply VDD via the resistor element R3. In other words, when a pre-emphasis bit occurs in Period (1), the NMOS transistors N5 and N6 in the de-emphasis level controller 30 do not influence the circuit operation. OUTB goes to the Low voltage VOLP, and OUTT the High voltage VOHP. Assuming that the drain currents of the NMOS transistors N1 and N3 are I1 and I3, the Low voltage VOLP is given:

VOLP=VDD−R1×(I1+I3).

The High voltage VOHP at OUTT is equal to the power supply voltage VDD since the NMOS transistors N2 and N4 are OFF.

### [Period (2)]

(INT, INB)=(High, Low), and (EMT, EMB)=(Low, High) as in FIG. 6. The NMOS transistors N1 in the driver main buffer 10 maintains the ON state, the NMOS transistor N2 maintains the OFF state, the NMOS transistor N3 in the pre-emphasis buffer 20 turns OFF, the NMOS transistor N4 turns ON, and OUTT and OUTB go to the de-emphasized High voltage VOHD and Low voltage VOLD, respectively.

During Period (2), in the de-emphasis level controller 30, the NMOS transistor N6 turns ON and the NMOS transistor N5 turns OFF as in Period (1). In other words, at a time of de-emphasis, the transistor pair of the NMOS transistors N3 and N5 both turn OFF, and the transistor pair of the NMOS transistors N4 and N6 both turn ON. A current flows from the high-potential power supply VDD to the low-potential power supply VSS via the third resistor element R3 and the NMOS transistors N6 and N12.

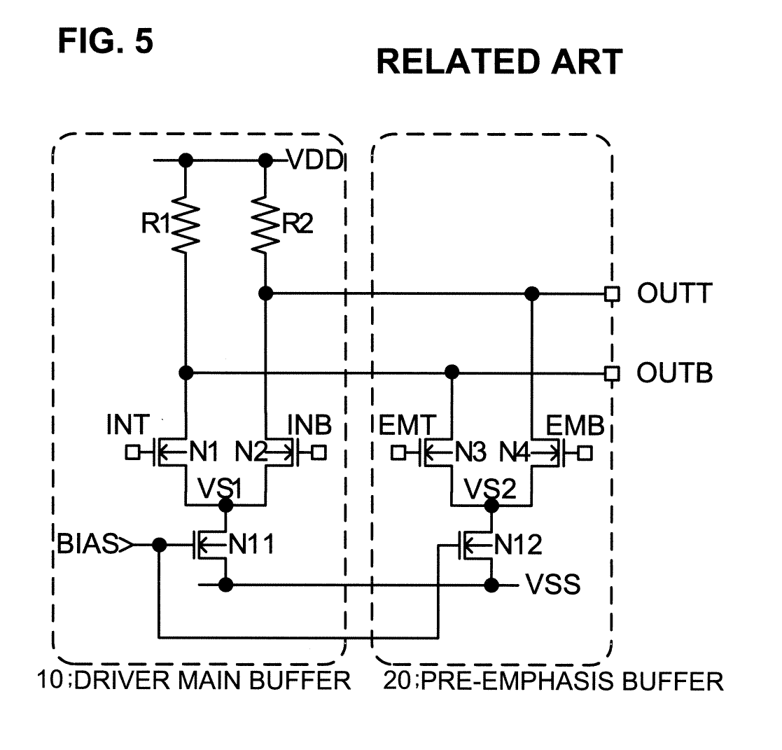

In the circuit of the related technology shown in FIG. 5, the NMOS transistor N4 having a drain connected to OUTT turns ON, the voltage at the drain node VS2 of the current source transistor N12 drops from Va to Vb (refer to FIG. 6), and a drain current (de-emphasis circuit current) of the NMOS transistor N4 increases during Period (2). As a result, the voltage drop of the resistor element R2 increases, the drop of the High voltage (VOHD) at OUTT increases, and the common mode voltage VCM is lowered as compared with the voltage at a time of pre-emphasis.

On the other hand, according to the present example, the NMOS transistor N6 having a source connected to that of the NMOS transistor N4 connected to OUTT is connected to the high-potential power supply VDD via the resistor element R3 in the de-emphasis level controller 30, and during Period (2) at a time of de-emphasis, due to the fact that the NMOS transistors N4 and N6 both turn ON, a current is flown by the NMOS transistor N6 to the power supply VSS, and a de-emphasis current (the drain current of the NMOS transistor N4) flowing through the resistor element R2 is limited, thereby inhibiting the drop of the High voltage (VOHD) at OUTT at a time of de-emphasis, and the decrease in the common mode voltage VCM is mitigated.

Further, when the resistance value of the resistor element R3 is increased, during Period (2), the voltage drop of the resistor element R3 caused by the current flowing through the NMOS transistor N6 in the ON state increases, the voltage at the drain node VS3 of the NMOS transistor N13 (the current source) decreases, and the current flowing through the NMOS transistor N13 decreases. Therefore, the drain current of the NMOS transistor N4 decreases, and the High voltage (VOHD) at OUTT drops even less at a time of de-emphasis, compared to VOHP when a pre-emphasis bit occurs. Further, during Period (2), the NMOS transistor N3 turns OFF, and OUTB goes to the Low voltage (VOLD) due to the current (I1) flowing through the NMOS transistor N1 in the ON state. (VOLD=VDD−R1×I1.) This is higher than the Low voltage VOLP (=VDD−R1×(I1+I3)) at OUTB during Period (1).

### [Period (3)]

When (INT, INB) transition to (Low, High) from (High, Low) and (EMT, EMB)=(Low, High) as in FIG. 6, the NMOS transistor N2 in the driver main buffer 10 turns ON, and the NMOS transistor N4 in the pre-emphasis buffer 20 turns ON. The NMOS transistor N1 in the driver main buffer 10 turns OFF, and the NMOS transistor N3 in the pre-emphasis buffer 20 turns OFF. OUTT goes to the Low voltage VOLP equal to a value obtained by subtracting, from the power supply voltage VDD, an amount of the voltage drop across the second resistor (R2) caused by a sum of the currents flowing through the NMOS transistors N2 and N4 in the ON state (sum of the currents of the current sources N11 and N13). Assuming that I2 and I4 are drain currents flowing through the NMOS transistors N2 and N4, VOLP is given:

VOLP=VDD−R2×(I2+I4). OUTB goes to the High voltage VOHP (=the power supply voltage VDD) since the transistors N1 and N3 are OFF.

At this time, the NMOS transistor N5 turns ON and the NMOS transistor N6 OFF in the de-emphasis level controller 30. The NMOS transistor N5 turns ON, and a current flows from the high-potential power supply VDD via the resistor element R3. Since the NMOS transistor N6 having a source connected to that of the NMOS transistor N4 is OFF, no current flows from the high-potential power supply VDD, and the NMOS transistors N5 and N6 do not influence the circuit operation. The common mode voltage VCM during Period (3) is equal to that during Period (1). Therefore, the common mode voltage VCM during Period (3) is equal to that during Period (2).

### [Period (4)]

When (INT, INB) are maintained at (Low, High), (EMT, EMB) are set to (High, Low) as in FIG. 6. The NMOS transistor N2 turns ON, the NMOS transistor N4 turns OFF, the NMOS transistor N1 turns OFF, and the NMOS transistor N3 turns ON. OUTT and OUTB have the de-emphasized waveforms. During Period (4), at a time of de-emphasis, the transistor pair of the NMOS transistors N3 and N5 both turn ON, and the transistor pair of the NMOS transistors N4 and N6 both turn OFF.

In the circuit shown in FIG. 5, during Period (4), the NMOS transistor N3 having its drain connected to OUTB turns ON, the voltage at the drain node VS2 of the current source transistor N12 increases from Va to Vb (refer to FIG. 6), and a drain current (the de-emphasis current) of the NMOS transistor N3 increases. As a result, a voltage drop across the resistor element R1 increases and so does the drop of the High voltage (VOHD) at OUTB, and hence the common mode voltage VCM decreases from the value at a time of pre-emphasis.

On the other hand, according to the present example, the NMOS transistor N5 having a source connected to that of the NMOS transistor N3 connected to OUTB is connected to the high-potential power supply VDD in the de-emphasis level controller 30, and because the NMOS transistors N3 and N5 both turn ON, the NMOS transistor N5 lets a current flow to the power supply, a current (drain current) flowing through the NMOS transistor N3 is reduced, and the value of a current flowing through the resistor element R1 at a time of de-emphasis is reduced, so that the drop of the High voltage (VOHD) at OUTB at a time of de-emphasis is mitigated and the decrease in the common mode voltage VCM is mitigated.

Further, when the resistance value of the resistor element R3 is increased, the voltage drop of the resistor element R3 caused by a current flowing through the NMOS transistor N5 in an ON state increases, the voltage at the drain node VS2 of the NMOS transistor N12 decreases, and the current flowing through the NMOS transistor N12 decreases. Therefore, the drain current of the NMOS transistor N3 decreases even more, and the High voltage (VOHD) at OUTB drops even less, as compared to VOHP. Further, during Period (4), the NMOS transistor N4 turns OFF, and OUTT goes to the Low voltage (VOLD) due to the current (I2) flowing through the NMOS transistor N2 in an ON state. As a result,

VOLD=VDD−R2×I2

This is higher than the Low voltage VOLP VDD−R2×(I2+I4)) at OUTB during Period (3). Further, during Period (4), (INT, INB) continue to be (Low, High) for two cycles.

In Periods (5) to (11) in FIG. 2, Periods (1) to (4) are also repeated. During Period (11), (INT, INB) continue to be (High, Low) for three consecutive cycles.

### Example 2

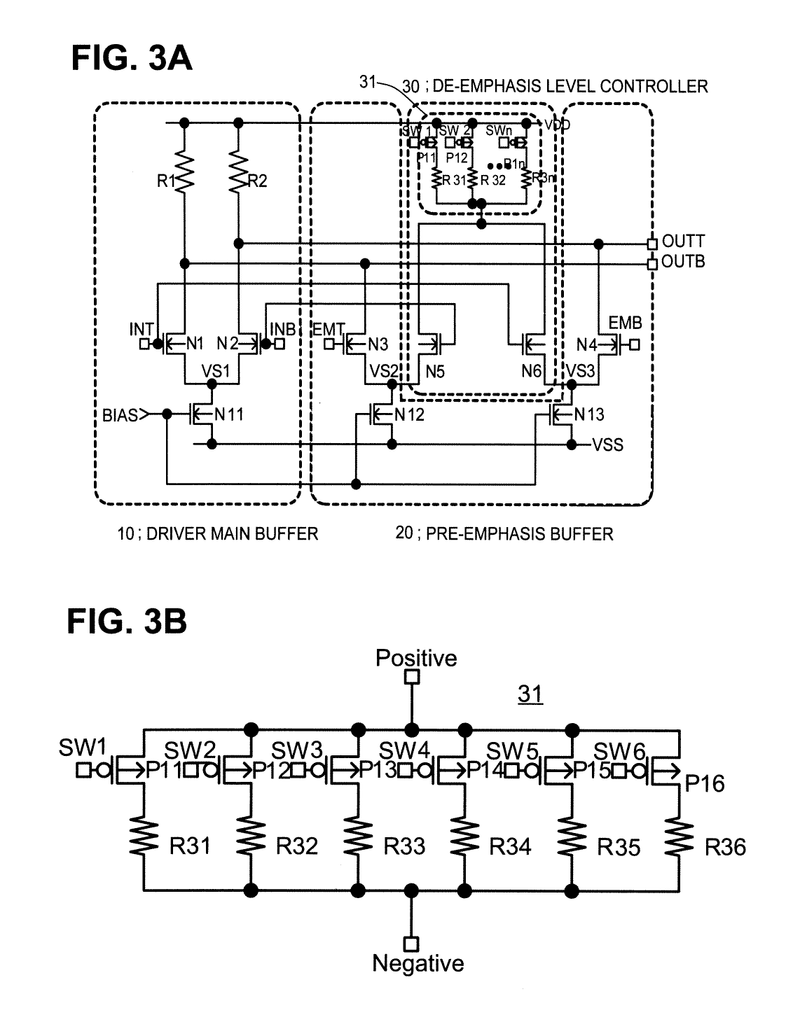

FIGS. 3A and 3B are diagrams showing the configuration of a second example of the present invention. With reference to FIG. 3A, the resistor element R3 in FIG. 1 is replaced with a variable resistance unit 31 in the present example. In the present example, the variable resistance unit 31 comprises a plurality of resistor elements R31, R32, . . . , and R3n (n is a predetermined positive integer) and a plurality of PMOS transistors P11, P12, . . . , and Pin respectively connected between the resistor elements R31, R32, . . . , and R3n and the high-potential power supply VDD, and is able to select any resistance value by controlling control signals SW1, SW2, . . . , and SWn respectively connected to gates of the PMOS transistors P11, P12, and Pln. FIG. 3B shows the configuration of the variable resistance unit 31 when n=6. The resistor elements R31 to R36 and the PMOS transistors P11, P12, . . . , and P16 are provided. When one or more control signals SW1 to SW6 is at a Low level, the corresponding PMOS transistors turn ON and the corresponding resistors are connected in parallel. When the resistance values of the resistor elements R31 to R36 are all different from each other, the parallel composite resistor element R3 is able to select from 63 different composite resistance values from when only one is turned ON (R31 to R36) to all the six switches are turned ON:

1/R3=1/R31+1/R32+ . . . 1/R36.

When the resistance values of the resistor elements R31 to R36 are the same, the selection is made from five different resistance values.

As a result, the unit can select the optimum resistance value corresponding to different output amplitudes and pre-emphasis ratios each defined in standard interface protocols such as PCI Express, Serial ATA, and CEI.

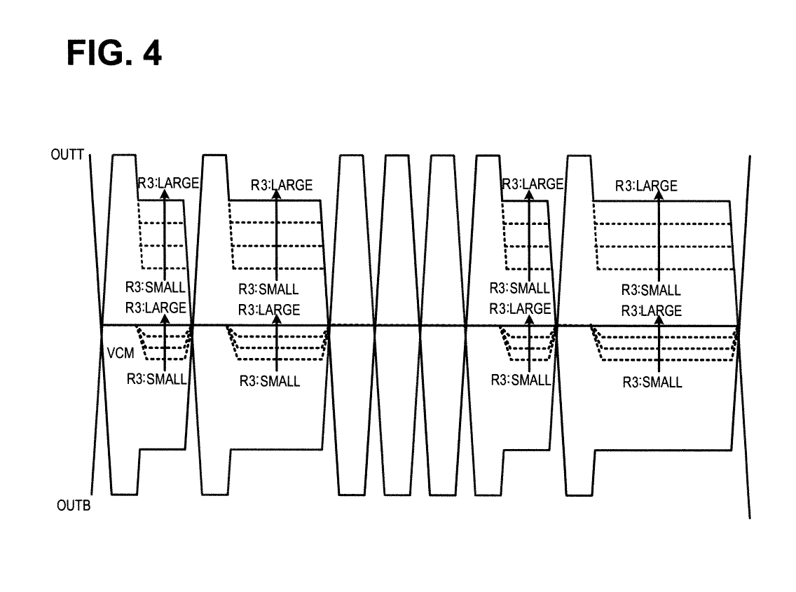

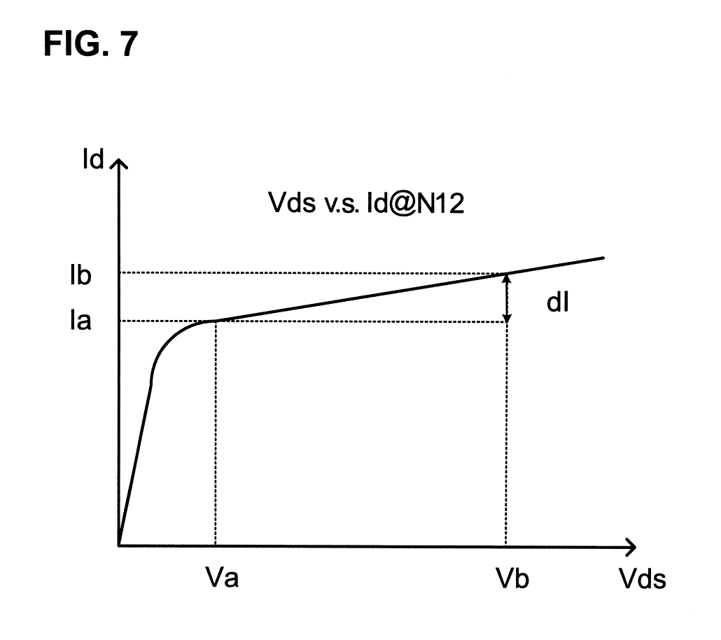

FIG. 4 is a waveform diagram for explaining the operation of the present example and schematically shows the relations among the High voltage at OUTT/OUTB at a time of de-emphasis, the common mode voltage VCM, and the resistor element R3. The diagram illustrates that the High voltage (VOHD) at a time of de-emphasis increases and the common mode voltage VCM gets closer to that at a time of pre-emphasis when the resistance value of the resistor element R3 is increased. As described, this is because, when the resistance value of the resistor element R3 is increased, the voltage drop of the resistor element R3 caused by the current flowing through, for instance, the NMOS transistor N6 in a ON state increases, the drain voltage of the transistor N13 decreases, the drain current of the NMOS transistor N4 decreases (refer to FIG. 7), and the drop amount of the High voltage VOHD at OUTT from VOHP is reduced as a result. When VOHD increases, VCM (=(VOHD+VOLD)/2) increases as well and becomes closer to VCM at a time of pre-emphasis.

The effects of the present example will be described below.

According to the present example, by optimizing the level of the common mode voltage at a time of de-emphasis so that it is equal to that in transition bits, fluctuations in VCM is decreased, and specifications regarding a VCM variation defined by standard interface protocols (PCI Express, Serial ATA, and CEI) can be supported.

According to the present example, since the circuit is constituted by differential pairs operating at the same speed as the output circuit, improvement effects for high-speed fluctuations in VCM between transition bits with a value change and de-emphasis bits with the same value as in the previous cycle can be exhibited.

Further, according to the present example, by providing the variable resistance unit 31 so that the resistant value of the resistor element can be adjusted externally as in the configuration shown in FIGS. 3A and 3B, an improvement can be made without redesigning the circuit when differences in a VCM variation between the design and the actual device occur.

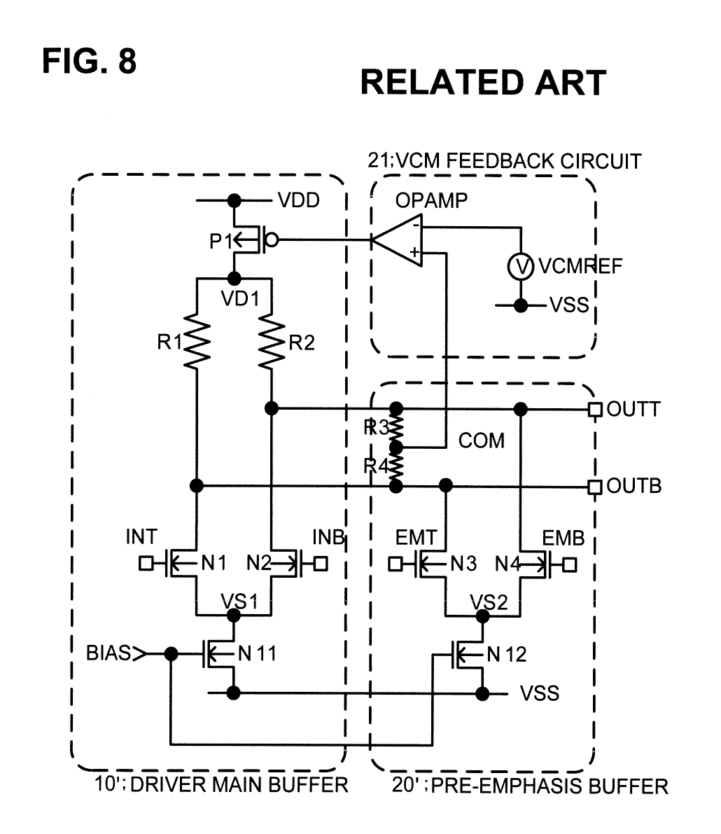

As described, in order to follow the high-speed fluctuations in VCM between a transition bit and a de-emphasis bit in high-speed interfaces (PCI Express, Serial ATA, and CEI), the VCM variation must be mitigated at the same speed as the output data of the output circuit. Differing from the general configuration in which VCM is stabilized by a feedback circuit (refer to FIG. 8) using an operational amplifier and having a slow following speed, the present example has the configuration in which the transistor pair (N5, N6) operating at the same speed as the output data is added to the pre-emphasis buffer (N3, N4); therefore the circuit is able to follow the high-speed fluctuations in VCM.

Further, according to the present example, the VCM fluctuation value can be reduced by reducing the current only at a time of de-emphasis and optimizing the circuit so that VCM at a time of de-emphasis is equal to that in transition bits.

Further, according to the present example, since existing signals (conventional signals) such as EMT and EMB can be used as input signals as they are, additional control circuits are not required. For instance, this is effective for an output circuit having a configuration in which common mode voltage VCM varies between a transition bit and a de-emphasis bit such as a case where a de-emphasis waveform having a large amplitude is outputted with a low power supply voltage.

The circuits constituted by NMOS transistors are shown in the examples in FIGS. 1, 3A, and 3B, however, in the present invention, transistors are not limited to NMOS transistors. For instance, PMOS transistors can be used to constitute the circuit. In this case, sources of PMOS transistors constituting the current sources are connected to VDD, and the resistor elements R1, R2, and R3 are connected between drains of the PMOS transistors and VSS.

The disclosures of the aforementioned Patent Documents are incorporated by reference herein. The particular exemplary embodiments may be modified or adjusted within the gamut of the entire disclosure of the present invention, inclusive of claims, based on the fundamental technical concept of the invention. Further, variegated combinations or selection of elements disclosed herein may be made within the framework of the claims. That is, the present invention may encompass various modifications or corrections that may occur to those skilled in the art in accordance with the gamut of the entire disclosure of the present invention, inclusive of claim and the technical concept of the present invention.

What is claimed is:

1. An output circuit that receives an input signal and that outputs differentially a pre-emphasized output signal when said input signal transitions, said output circuit comprising:
a transistor applying de-emphasis to said output signal, said transistor being made conductive responsive to a control signal applied to a control terminal thereof at a time of de-emphasis when said input signal does not change from a pre-emphasis state; and
a de-emphasis level control circuit performing control to reduce an amount of a variation in a common mode voltage of said output signal, which is differentially output, from a pre-emphasis state to a de-emphasis state, said de-emphasis level control circuit including
another transistor controlling a de-emphasis level of said output signal,
said another transistor and said transistor applying de-emphasis to said output signal having first terminals connected in common to a current source which is connected to a first power supply and having second terminals connected to a second power supply and an output terminal outputting said output signal, respectively,
said another transistor being made conductive at a time of de-emphasis to limit a current flowing through said transistor applying de-emphasis to said output signal at a time of de-emphasis.

2. The output circuit according to claim 1, wherein said output circuit differentially receives said input signal and a complementary signal of said input signal, and outputs differentially said output signal and a complementary signal of said output signal, and wherein
said de-emphasis level control circuit limits a current flowing through said transistor that applies de-emphasis to said output signal which is on a side of said second power supply potential, out of said differential output signals, and reduces a variation in a common mode voltage of said differential output signals from a pre-emphasis state to a de-emphasis state.

3. The output circuit according to claim 1, wherein said another transistor is controlled to be conductive and nonconductive based on a value of said input signal applied to a control terminal thereof.

4. The output circuit according to claim 1, wherein said de-emphasis level control circuit comprises
a resistor connected between said second terminal of said another transistor and said second power supply.

5. The output circuit according to claim 4, wherein said resistor has a resistance value being able to be set variably.

6. The output circuit according to claim 1, comprising:
a first transistor pair including first and second transistors;
a second transistor pair including third and fifth transistors;
a third transistor pair including fourth and sixth transistors;
first to third current sources respectively connected between said first to said third transistor pairs and a first power supply;
first and second input terminals supplied with input signals complementary to each other;
first and second output terminals outputting differentially output signals,
first and second resistor elements respectively connected between said first and said second output terminals and a second power supply;
a third resistor having a first end connected to said second power supply;
a first control signal terminal supplied with a first control signal that is for controlling pre-emphasis processing; and
a second control signal terminal supplied with a second control signal control complementary to said first control signal, wherein
said first and said second transistors have first terminals connected in common to said first current source, have control terminals connected to said first and second input terminals, respectively, and have second terminals connected to said first and second output terminals, respectively;
said third and said fifth transistors have first terminals connected in common to said second current source, have control terminals connected to said first control signal terminal and said second input terminal, respectively, and have second terminals connected to said first output terminal and a second end of said third resistor, respectively, and
said fourth and said sixth transistors have first terminals connected in common to said third current source, have control terminals connected to said second control signal terminal and said first input terminal, respectively, and have second terminals connected to said second output terminal and said second end of said third resistor, respectively
said fourth transistor and said sixth transistor constituting a first set of said transistor applying de-emphasis and said another transistor controlling a de-emphasis level for said output signal output at said first output terminal, and said third transistor and said fifth transistor constituting a second set of said transistor applying de-emphasis and said another transistor controlling a de-emphasis level for said output signal output at said second output terminal.

7. The output circuit according to claim 6, wherein said third resistor includes a variable resistance unit having a resistance value variably set.

8. The output circuit according to claim 7, wherein said variable resistance unit is constituted by a plurality of series circuits of resistors and switches connected in parallel and has its resistance value varied by controlling ON/OFF of said switches based on switch control signals.

9. A semiconductor device comprising said output circuit according to claim 1.

10. A semiconductor device comprising:
a first transistor pair including first and second transistors;
a second transistor pair including third and fifth transistors;
a third transistor pair including fourth and sixth transistors;
first to third current sources respectively connected between said first to said third transistor pairs and a first power supply,
first and second input terminals supplied with input signals complementary to each other;
first and second output terminals outputting differentially output signals,
first and second resistor elements respectively connected between said first and said second output terminals and a second power supply;
a third resistor having a first end connected to said second power supply;
a first control signal terminal supplied with a first control signal that is for controlling pre-emphasis processing; and
a second control signal terminal supplied with a second control signal control complementary to said first control signal, and wherein
said first and said second transistors have first terminals connected in common to said first current source, have control terminals connected to said first and second input terminals, respectively, and have second terminals connected to said first and second output terminals, respectively;
said third and said fifth transistors have first terminals connected in common to said second current source, have control terminals connected to said first control signal terminal and said second input terminal, respectively, and have second terminals connected to said first output terminal and a second end of said third resistor, respectively, and
said fourth and said sixth transistors have first terminals connected in common to said third current source, have control terminals connected to said second control signal terminal and said first input terminal, respectively, and have second terminals connected to said second output terminal and said second end of said third resistor, respectively.
